(19) United States
(12) Patent Application Publication
(10) Pub. No.: US 2024/0361697 A1
(43) Pub. Date: Oct. 31, 2024

(54) METHOD FOR SELECTING PHOTOSENSITIVE RESIN COMPOSITION, METHOD FOR PRODUCING PATTERNED CURED FILM, CURED FILM, SEMICONDUCTOR DEVICE, AND METHOD FOR PRODUCING SEMICONDUCTOR DEVICE

(71) Applicant: Resonac Corporation, Tokyo (JP)

(72) Inventors: Yuki IMAZU, Tokyo (JP); Kazuyuki MITSUKURA, Tokyo (JP); Masaya TOBA, Tokyo (JP); Yu AOKI, Tokyo (JP); Takuya KOMINE, Tokyo (JP)

(21) Appl. No.: 18/560,234

(22) PCT Filed: May 14, 2021
(86) PCT No.: PCT/JP2021/018417

§ 371 Date: Nov. 10, 2023

(51) Int. Cl. G03F 7/16; G01N 5/04; G03F 7/038; G03F 7/039; H01L 21/027

(52) U.S. Cl. CPC G03F 7/168; G01N 5/04; G03F 7/038; G03F 7/039; H01L 21/0274

(57) ABSTRACT

The present disclosure relates to a method for selecting a photosensitive resin composition, the method including: a step of applying a photosensitive resin composition on a substrate and drying the photosensitive resin composition to form a resin film; a step of heat-treating the resin film in a nitrogen atmosphere to obtain a cured film; and a step of raising the temperature from 25° C. to 300° C. at a rate of 10° C./min in a nitrogen atmosphere and then measuring weight loss of the cured film, in which a photosensitive resin composition capable of producing the cured film having a weight loss ratio at 300° C. of 1.0% to 6.0% is selected.

### TECHNICAL FIELD

The present invention relates to a method for selecting a photosensitive resin composition, a method for producing a patterned cured film, a cured film, a semiconductor device, and a method for producing a semiconductor device.

### BACKGROUND ART

In order to achieve high-speed transmission and miniaturization of semiconductor devices, there have been proposed semiconductor packages in which materials having different physical properties are combined in a complex manner to promote density increase. In such a semiconductor package, in order to form a fine pattern, a cured film formed from a material capable of forming a wiring pattern by exposure, or a cured film for protecting wiring by filling the space between the wiring lines of a fine pattern, is applied.

As the performance of electronic instruments is increasingly improved, semiconductor elements are becoming more highly integrated and more highly reliable year after year. As semiconductor elements are becoming more highly integrated, it is required to form even finer wiring patterns. As wiring lines are formed with narrower pitches, a cured film is required to have more excellent HAST (Highly Accelerated Stress Test) resistance. Since the importance of insulation reliability between fine wiring lines is more emphasized, it has been investigated to improve the HAST resistance of cured films under the conditions with a higher test temperature such as 130° C. and 85% RH, as compared to conventional tests of applying voltage at 85° C. and 60% RH or at 85° C. and 85% RH (see, for example, Patent Literature 1 and Non Patent Literature 1).

### CITATION LIST

### Patent Literature

Patent Literature 1: JP 2020-143238 A

### Non Patent Literature

Non Patent Literature 1: “Solder Resist for Next-Generation Electronic Circuit Board”, Journal of the Japan Institute of Electronics Packaging, Vol. 13, No. 5, pp. 396-399 (2010)

### SUMMARY OF INVENTION

### Technical Problem

An error mode in a HAST test indicates a sudden decrease in the resist value due to the occurrence of a short circuit between wiring lines. Generally, as a cause of the error mode, it is known that residual moisture in the cured film filled between wiring lines induces electrical continuity between the wiring lines. However, along with further narrowing of the wiring, the line width and the interline distance are further decreased, and in a HAST test with a line width of 3 μm or less and an interline distance of 3 μm or less, it is inappropriate to specify the presence or absence of the occurrence of an error mode only with the water absorption rate.

An object of the present disclosure is to provide a simple method for selecting a photosensitive resin composition for forming a cured film having excellent HAST resistance, a cured film having excellent HAST resistance, a method for producing a patterned cured film, a semiconductor device, and a method for producing a semiconductor device.

### Solution to Problem

An aspect of the present disclosure relates to a method for selecting a photosensitive resin composition, the method including: a step of applying a photosensitive resin composition on a substrate and drying the photosensitive resin composition to form a resin film; a step of heat-treating the resin film in a nitrogen atmosphere to obtain a cured film; and a step of raising temperature from 25° C. to 300° C. at a rate of 10° C./min in a nitrogen atmosphere and then measuring weight loss of the cured film, in which a photosensitive resin composition capable of producing the cured film having a weight loss ratio at 300° C. of 1.0% to 6.0% is selected.

Another aspect of the present disclosure relates to a method for producing a patterned cured film, the method including: a step of applying a photosensitive resin composition selected by the above-mentioned method for selecting a photosensitive resin composition, on a portion or the entire surface of a substrate, and drying the photosensitive resin composition to form a resin film; a step of exposing at least a portion of the resin film; a step of developing the resin film after exposure to form a patterned resin film; and a step of heating the patterned resin film to obtain a patterned cured film.

Still another aspect of the present disclosure relates to a method for producing a semiconductor device including a patterned cured film formed by the above-described method for producing a patterned cured film as an interlayer insulating layer or a surface protection layer.

Another aspect of the present disclosure relates to a cured film of a photosensitive resin composition used for filling space between wiring lines with a line width of 3 μm or less and an interline distance of 3 μm or less, in which a weight loss ratio measured by raising temperature of the cured film from 25° C. to 300° C. at a rate of 10° C./min in a nitrogen atmosphere is 1.0% to 6.0%.

Still another aspect of the present disclosure relates to a semiconductor device including the above-described cured film as an interlayer insulating layer or a surface protection layer.

### Advantageous Effects of Invention

According to the present disclosure, a simple method for selecting a photosensitive resin composition, by which a cured film having excellent HAST resistance can be formed, a cured film having excellent HAST resistance, a method for producing a patterned cured film, a semiconductor device, and a method for producing a semiconductor device can be provided.

### BRIEF DESCRIPTION OF DRAWINGS

FIG. 1 is a schematic cross-sectional view explaining an embodiment of a production process for a semiconductor device.

FIG. 2 is a schematic cross-sectional view explaining an embodiment of a production process for a semiconductor device.

FIG. 3 is a schematic cross-sectional view explaining an embodiment of a production process for a semiconductor device.

FIG. 4 is a schematic cross-sectional view explaining an embodiment of a production process for a semiconductor device.

FIG. 5 is a schematic cross-sectional view explaining an embodiment of a production process for a semiconductor device.

FIG. 6 is a schematic cross-sectional view illustrating an embodiment of an electronic component (semiconductor device).

FIG. 7 is a schematic cross-sectional view illustrating an embodiment of an electronic component (semiconductor device).

### DESCRIPTION OF EMBODIMENTS

Embodiments for carrying out the present disclosure will be described in detail below. However, the present invention is not intended to be limited to the following embodiments. According to the present specification, the term “step” includes not only an independent step but also a step that cannot be clearly distinguished from other steps, as long as the intended action of the step is achieved. According to the present specification, the term “layer” includes a structure having a shape formed over the entire surface as well as a structure having a shape formed in a portion, when viewed in a plan view.

According to the present specification, a numerical value range represented by using the term “to” indicates a range that includes the numerical values described before and after the term “to” as the minimum value and the maximum value, respectively. With regard to a numerical value range described stepwise in the present specification, the upper limit value or lower limit value of a numerical value range of a certain stage may be replaced with the upper limit value or lower limit value of a numerical value range of another stage. With regard to a numerical value range described in the present specification, the upper limit value or lower limit value of the numerical value range may be replaced with a value indicated in the Examples.

In a case where the amount of each component in a composition is mentioned in the present specification, when a plurality of substances corresponding to each component are present in the composition, unless particularly stated otherwise, the amount of each component means the total amount of the plurality of substances present in the composition. According to the present specification, the term “(meth)acrylic acid” means at least one of “acrylic acid” and “methacrylic acid” corresponding thereto. The same also applies to other similar expressions such as (meth)acrylate.

### Method for Selecting Photosensitive Resin Composition

A method for selecting a photosensitive resin composition according to the present embodiment includes: a step of applying a photosensitive resin composition on a substrate and drying the photosensitive resin composition to form a resin film; a step of heat-treating the resin film in a nitrogen atmosphere to obtain a cured film; and a step of raising temperature from 25° C. to 300° C. at a rate of 10° C./min in a nitrogen atmosphere and measuring weight loss of the cured film. Through this method, a photosensitive resin composition capable of producing the cured film having a weight loss ratio at 300° C. of 1.0% to 6.0% is selected.

When producing a semiconductor package, a cured film formed from a photosensitive resin composition is used in order to form a fine wiring pattern or in order to fill the space between fine wiring lines. The photosensitive resin composition may include a low-molecular weight additive for the purpose of improving the close adhesiveness between the wiring and the cured film. Since the low-molecular weight additive is easily degraded by heat, in the case of obtaining a cured film by a heat treatment, when the heat treatment temperature is increased, the additive is degraded, and the close adhesive between the wiring and the cured film may be deteriorated. The inventors of the present invention believe that when the weight loss ratio of the cured film is specified, the close adhesiveness between the wiring and the cured film is sufficiently secured, and the HAST resistance can be improved.

The procedure of the method for selecting a photosensitive resin composition according to the present embodiment will be described in detail below. First, a photosensitive resin composition is applied on a base material and dried to form a resin film. As the substrate, a silicon wafer, an organic substrate, or a glass substrate can be used from the viewpoint that processing is easy. As the coating method, from the viewpoint of general-purpose usability, spin coating, bar coating, slit coating, or spray coating can be used. The drying temperature may be 80° C. to 140° C., 90° C. to 135° C., or 100° C. to 130° C., and the drying time may be 1 to 7 minutes, 1 to 6 minutes, or 2 to 5 minutes.

Next, the substrate on which the resin film has been formed is heat-treated in a nitrogen atmosphere to form a cured film. The temperature for the heat treatment may be 170° C. to 260° C., 180° C. to 250° C., or 190° C. to 240° C. The time for the heat treatment may be 1.0 to 2.5 hours, 1.5 to 2.5 hours, or 1.8 to 2.2 hours.

The cured film is peeled off from the substrate, subsequently the temperature is raised using a simultaneous thermogravimetric-differential thermal analyzer, from 25° C. to 300° C. at a temperature increase rate of 10° C./min at a nitrogen flow rate of 400 mL/min, and the weight loss of the cured film is measured. As the analyzer, for example, “STA7300” manufactured by Hitachi High-Tech Science Corporation can be used.

The cured film according to the present embodiment is used in order to fill the space between wiring lines with a line width of 3 μm or less and an interline distance of 3 μm or less. The weight loss ratio at 300° C. as measured by raising the temperature of the cured film from 25° C. to 300° C. at a rate of 10° C./min in a nitrogen atmosphere is 1.0% to 6.0%.

From the viewpoint of reducing unreacted components remaining in the cured film to improve the HAST resistance, the weight loss ratio at 300° C. of the cured film is 6.0% or less, preferably 5.5% or less, and more preferably 5.0% or less. From the viewpoint of enhancing the close adhesiveness of the cured film to the substrate, the weight loss ratio at 300° C. of the cured film is 1.0% or more and may be 1.5% or more or 2.0% or more.

From the viewpoint of reducing the water content in the cured film to suppress the occurrence of a short circuit between wiring lines during a HAST test, the moisture absorption rate of the cured film after being left to stand for 24 hours under the conditions of 130° C. and 85 RH % is preferably 1.2% or less, more preferably 1.0% or less, and even more preferably 0.9% or less.

The moisture absorption rate can be measured by the following procedure. A substrate on which a cured film has been formed is left to stand for 24 hours in a constant-temperature constant-moisture chamber set at a temperature of 130° C. and a relative humidity of 85%, subsequently the temperature of the constant-temperature constant-humidity chamber is lowered to 50° C., and a measurement sample for the moisture absorption rate is fabricated, while as the constant-temperature constant-humidity chamber, for example, tradename “EHS-221MD” manufactured by ESPEC CORP. can be used. The cured film is peeled off from the measurement sample, subsequently the temperature is raised using a simultaneous thermogravimetric-differential thermal analyzer, from 25° C. to 150° C. at a temperature increase rate of 10° C./min at a nitrogen flow rate of 400 mL/min, and the weight loss ratio of the cured film is measured. In addition, a measurement sample fabricated under the same conditions is dried at 130° C. for 2 hours, and then the weight loss ratio of the cured film is measured by a similar method. The difference in the weight loss ratio at 150° C. is calculated as the moisture absorption rate.

The storage modulus at 130° C. of the cured film is preferably 1.0 GPa or more, more preferably 1.2 GPa or more, and even more preferably 1.4 GPa or more, from the viewpoint of reducing the stress at the time of deformation of the cured film occurring under high-temperature and high-humidity conditions. The storage modulus at 130° C. of the cured film may be 5.0 GPa or less, 4.0 GPa or less, or 3.0 GPa or less.

The storage modulus can be measured by the following procedure. A cured film is cut out into a strip form having a width of 10 mm and a length of 100 mm, and a strip sample of the cured film is fabricated. Using a dynamic viscoelasticity measuring apparatus, the temperature is raised from 40° C. to 350° C. at a temperature increase rate of 5° C./min at a distance between chucks of 20 mm and a frequency of 10 Hz, a viscoelasticity test of the strip sample is performed, and the storage modulus at 130° C. is measured.

The glass transition temperature (Tg) of the cured film is preferably 200° C. or higher and may be 200° C. to 300° C., 220° C. to 280° C., or 230° C. to 260° C., from the viewpoint of reducing thermal deformation of the cured film occurring due to the high-temperature conditions in a HAST test. Tg is the temperature showing the maximum value of tan δ.

### Photosensitive Resin Composition

The photosensitive resin composition according to the present embodiment may be a positive-type photosensitive resin composition or may be a negative-type photosensitive resin composition. From the viewpoint that fine patterning occurs, the photosensitive resin composition can include: (A) a base polymer, (B) a thermosetting compound or a photopolymerizable compound, and (C) a photosensitizer. Hereinafter, each component that can be contained in the photosensitive resin composition will be described in detail.

### Component (A): Base Polymer

As the component (A), a polymer having a phenolic hydroxyl group, a carboxyl group, an imide group, a benzoxazole group, or a photopolymerizable ethylenically unsaturated group can be used.

A polymer having a phenolic hydroxyl group may be an alkali-soluble resin. Examples of the polymer having a phenolic hydroxyl group include a polyimide resin, a polybenzoxazole resin, a polyamide resin, a phenol-formaldehyde condensate novolac resin, a cresol-formaldehyde condensed novolac resin, a phenol-naphthol-formaldehyde condensed novolac resin, a polyhydroxystyrene or a copolymer thereof, a phenol-xylylene glycol condensed resin, a cresol-xylylene glycol condensed resin, a phenol-dicyclopentadiene condensed resin, and an acrylic polymer having a phenolic hydroxyl group.

As the acrylic polymer having a phenolic hydroxyl group, for example, an acrylic polymer having a structural unit represented by the following Formula (1) can be used. In Formula (1), R₁ represents a hydrogen atom or a methyl group.

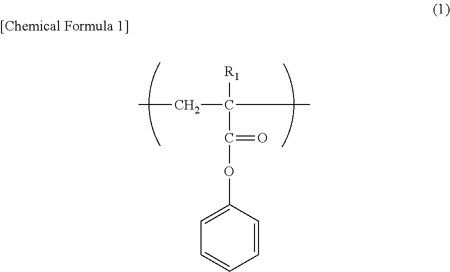

The phenolic hydroxyl group equivalent of the acrylic polymer having a phenolic hydroxyl group may be 200 to 700 g/eq, from the viewpoints of the pattern-forming properties and void reduction at the time of thermocompression bonding.

The acrylic polymer having a phenolic hydroxyl group may be a copolymer having a structural unit other than the structural unit represented by Formula (1) (hereinafter, simply referred to as “other structural unit”) together with the structural unit represented by Formula (1), and the other structural unit is a structural unit derived from a monomer copolymerizable with a monomer having a structural unit represented by Formula (1). The monomer having the other structural unit is not particularly limited; however, a (meth)acrylate compound or a vinyl compound can be used.

Examples of the monomer having the other structural unit include methyl (meth)acrylate, ethyl (meth)acrylate, propyl (meth)acrylate, butyl (meth)acrylate, octyl (meth)acrylate, methoxymethyl (meth)acrylate, methoxyethyl (meth)acrylate, ethoxyethyl (meth)acrylate, butoxyethyl (meth)acrylate, methoxyethoxyethyl (meth)acrylate, (meth)acrylic acid, hydroxyethyl (meth)acrylate, (meth)acrylonitrile, dihydrodicyclopentenyl (meth)acrylate, dihydrodicyclopentenyl itaconate, dihydrodicyclopentenyl maleate, dihydrodicyclopentenyl fumarate, dihydrodicyclopentenyloxyethyl (meth)acrylate, dihydrodicyclopentenyloxyethyl itaconate, dihydrodicyclopentenyloxyethyl maleate, dihydrodicyclopentenyloxyethyl fumarate, divinyl itaconate, divinyl maleate, divinyl fumarate, dicyclopentadiene, methyldicyclopentadiene, ethylidene norbornene, vinyl (meth)acrylate, 1,1-dimethylpropenyl (meth)acrylate, 3,3-dimethylbutenyl (meth)acrylate, vinyl 1,1-dimethylpropenyl ether, vinyl 3,3-dimethylbutenyl ether, 1-(meth)acryloyloxy-1-phenylethene, and 1-(meth)acryloyloxy-2-phenylethene.

The polymer having a carboxyl group may be an alkali-soluble resin. The polymer having a carboxyl group is not particularly limited; however, an acrylic polymer having a carboxyl group in a side chain is preferably used.

As the component (A), (A1) an alkali-soluble resin having a glass transition temperature (Tg) of 150° C. or higher and (A2) an alkali-soluble resin having a Tg of 120° C. or lower may be mixed and used. By adopting such a configuration, a cured film having more excellent reliability is obtained.

When (A1) an alkali-soluble resin having a Tg of 150° C. or higher and (A2) an alkali-soluble resin having a Tg of 120° C. or lower are mixed, it is preferable to blend 5 to 30 parts by mass of (A2) with respect to 100 parts by mass of (A1). When the blending amount of (A2) is 5 parts by mass or more, elongation of the cured film is less likely to be impaired, and the HAST resistance tends to be improved, whereas when the blending amount of (A2) is 30 parts by mass or less, the strength of the cured film is less likely to be impaired, while the HAST resistance tends to be improved.

As the component (A), an alkali-soluble resin having an imide group may be included, from the viewpoint of further improving the HAST resistance. As the alkali-soluble resin having an imide group, from the viewpoint that the concentration of imide groups can be arbitrarily adjusted, an acrylic polymer obtained by polymerizing a (meth)acrylate compound having an imide group is preferably used. As the alkali-soluble resin having an imide group, an alkali-soluble polyimide can also be used. From the viewpoint of resolution, it is preferable to use the alkali-soluble resin having an imide group in combination with a novolac resin or a phenol resin.

The alkali-soluble resin having an imide group may also be a copolymer of a (meth)acrylate compound having an imide group and a (meth)acrylate compound having a phenolic hydroxyl group or a carboxyl group.

As the polymer having a photopolymerizable ethylenically unsaturated group, for example, a polyimide precursor such as a polyamic acid ester in which all or some of carboxyl groups in polyamic acid have been esterified, may be mentioned. It is preferable that the polyamic acid ester has a photopolymerizable ethylenically unsaturated group. The polyamic acid ester may be a reaction product of a diamine, a tetracarboxylic acid dianhydride, and a compound having a photopolymerizable ethylenically unsaturated group.

Examples of the diamine include polyoxypropylenediamine and 2,2′-dimethylbiphenyl-4,4′-diamine (DMAP). Examples of the tetracarboxylic acid dianhydride include 4,4′-diphenyl ether tetracarboxylic acid dianhydride (ODPA). Examples of the compound having a photopolymerizable ethylenically unsaturated group include 2-hydroxyethyl (meth)acrylate (HEMA).

The Tg of the component (A) is the peak temperature of tan δ when measurement is made for a film of the component (A) by using a viscoelasticity analyzer (manufactured by Rheometric Scientific, Inc., trade name: RSA-2) under the conditions of a temperature increase rate of 5° C./min, a frequency of 1 Hz, and a measurement temperature of −50° C. to 300° C.

The weight average molecular weight (Mw) of the component (A) may be 3000 to 200000, 3500 to 100000, 4000 to 80000, or 4500 to 50000. The Mw of the alkali-soluble resin of (A1) is preferably 3000 to 50000, and from the viewpoint of reliability, the Mw may be 3500 to 30000, or from the viewpoint of resolution at the time of pattern formation, the Mw may be 4000 to 30000. The Mw of the alkali-soluble resin of (A2) is preferably 10000 to 100000, and from the viewpoint of reliability, the Mw may be 15000 to 80000, or from the viewpoint of resolution at the time of pattern formation, the Mw may be 15000 to 70000.

According to the present specification, the Mw is a value obtained by making measurement by gel permeation chromatography (GPC) method and converting the results from a standard polystyrene calibration curve. As the measuring apparatus, for example, high-performance liquid chromatography (manufactured by SHIMADZU CORPORATION, trade name: C-R4A) can be used.

### Component (B): Thermosetting Compound or Photopolymerizable Compound

As the component (B), a thermosetting compound or a photopolymerizable compound can be used. Regarding the component (B), one kind thereof may be used alone, or two or more kinds thereof may be used in combination.

Examples of the thermosetting compound include an acrylate resin, an epoxy resin, a cyanate ester resin, a maleimide resin, an allyl nadimide resin, a phenol resin, a urea resin, a melamine resin, an alkyd resin, an unsaturated polyester resin, a diallyl phthalate resin, a silicone resin, a resorcinol formaldehyde resin, a triallyl cyanurate resin, a polyisocyanate resin, a resin containing tris(2-hydroxyethyl) isocyanurate, a resin containing triallyl trimellitate, and a thermosetting resin synthesized from cyclopentadiene. From the viewpoints of insulation reliability of the photosensitive resin composition and the close adhesiveness to metals, the thermosetting resin is more preferably a compound having any one selected from a methylol group, an alkoxyalkyl group, and a glycidyl group.

By blending a compound having a glycidyl group as a component (B) into the photosensitive resin composition, when the resin film after pattern formation is heated and cured, the compound having a glycidyl group reacts with the component (A) and forms a bridged structure. As a result, brittleness and melting of the cured film can be prevented. As the compound having a glycidyl group, conventionally known ones can be used. Examples of the compound having a glycidyl group include a bisphenol A epoxy resin, a bisphenol F epoxy resin, a phenol novolac epoxy resin, a cresol novolac epoxy resin, an alicyclic epoxy resin, glycidylamine, a heterocyclic epoxy resin, and a polyalkylene glycol diglycidyl ether.

As the photopolymerizable compound, a compound having a photopolymerizable ethylenically unsaturated group can be used. Examples of the photopolymerizable compound include an α,β-unsaturated carboxylic acid ester of a polyhydric alcohol, a bisphenol-type (meth)acrylate, an α,β-unsaturated carboxylic acid adduct of a glycidyl group-containing compound, a (meth)acrylate having a urethane bond, nonylphenoxy polyethyleneoxy acrylate, a (meth)acrylate having a phthalic acid skeleton, and a (meth)acrylic acid alkyl ester.

Examples of the α,β-unsaturated carboxylic acid ester of a polyhydric alcohol include a polyethylene glycol di(meth)acrylate having 2 to 14 ethylene groups, a polypropylene glycol di(meth)acrylate having 2 to 14 propylene groups, a polyethylene polypropylene glycol di(meth)acrylate having 2 to 14 ethylene groups and 2 to 14 propylene groups, trimethylolpropane di(meth)acrylate, trimethylolpropane tri(meth)acrylate, EO-modified trimethylolpropane tri(meth)acrylate, PO-modified trimethylolpropane tri(meth)acrylate, EO- and PO-modified trimethylolpropane tri(meth)acrylate, tetramethylolmethane tri(meth)acrylate, tetramethylolmethane tetra(meth)acrylate, and a (meth)acrylate compound having a dipentaerythritol- or pentaerythritol-derived skeleton. The term “EO-modified” means having a block structure of an ethylene oxide (EO) group, and the term “PO-modified” means having a block structure of a propylene oxide (PO) group.

From the viewpoints of the developability of the resin film and the physical properties of the cured film, the content of the component (B) in the photosensitive resin composition may be 1 to 30 parts by mass, 2 to 28 parts by mass, or 3 to 25 parts by mass, with respect to 100 parts by mass of the component (A).

### Component (C): Photosensitizer

As the (C) photosensitizer, a photoradical polymerization initiator generating radicals when irradiated with light, or a photo-acid generator that generates acid when irradiated with light, can be used.

Examples of the photoradical polymerization initiator include an alkylphenone-based photopolymerization initiator, an acylphosphine-based photopolymerization initiator, an intramolecular hydrogen abstraction type photopolymerization initiator, and a cation-based photopolymerization initiator. Examples of commercially available products of these photopolymerization initiators include Omnirad 651, Omnirad 184, Omnirad 1173, Omnirad 2959, Omnirad 127, Omnirad 907, Omnirad 369, Omnirad 379EG, Omnirad 819, Omnirad MBF, Omnirad TPO, and Omnirad 784 manufactured by IGM Resins B.V.; Irgacure OXE01, Irgacure OXE02, Irgacure OXE03, and Irgacure OXE04 manufactured by BASF. Regarding the photoradical polymerization initiators, one kind thereof may be used alone, or two or more kinds thereof may be used in combination, according to the purpose, use application, and the like.

A photo-acid generator has a function of generating acid upon irradiation with light and increasing the solubility of the light-irradiated portion in an alkali aqueous solution. Examples of the photo-acid generator include an o-quinone diazide compound, an aryl diazonium salt, a diaryl iodonium salt, and a triaryl sulfonium salt. Regarding the photo-acid generators, one kind thereof may be used alone, or two or more kinds thereof may be used in combination, according to the purpose, use application, and the like.

It is preferable to use an o-quinone diazide compound as the photo-acid generator since the compound has high sensitivity. As the o-quinone diazide compound, for example, a compound obtainable by subjecting o-quinone diazide sulfonyl chloride, a hydroxy compound, an amino compound, and the like to a condensation reaction in the presence of a dehydrochlorination agent can be used. The reaction temperature may be 0° C. to 40° C., and the reaction time may be 1 to 10 hours.

Examples of o-quinone diazide sulfonyl chloride include benzoquinone-1,2-diazide-4-sulfonyl chloride, naphthoquinone-1,2-diazide-5-sulfonyl chloride, and naphthoquinone-1,2-diazide-6-sulfonyl chloride.

Examples of the hydroxy compound include hydroquinone, resorcinol, pyrogallol, bisphenol A, bis(4-hydroxyphenyl)methane, 1,1-bis(4-hydroxyphenyl)-1-[4-{1-(4-hydroxyphenyl)-1-methylethyl}phenyl]ethane, 2,2-bis(4-hydroxyphenyl)hexafluoropropane, 2,3,4-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3′,4′,5′-hexahydroxybenzophenone, bis(2,3,4-trihydroxyphenyl)methane, bis(2,3,4-trihydroxyphenyl)propane, 4b,5,9b,10-tetrahydro-1,3,6,8-tetrahydroxy-5,10-dimethylindeno[2,1-a]indene, tris(4-hydroxyphenyl)methane, and tris(4-hydroxyphenyl)ethane.

Examples of the amino compound include p-phenylenediamine, m-phenylenediamine, 4,4′-diaminodiphenyl ether, 4,4′-diaminodiphenylmethane, 4,4′-diaminodiphenylsulfone, 4,4′-diaminodiphenyl sulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane, and bis(4-amino-3-hydroxyphenyl)hexafluoropropane.

From the viewpoint of the reactivity when synthesizing an o-quinone diazide compound and from the viewpoint of having an appropriate absorption wavelength range when exposing the resin film, it is preferable to use a product obtained by subjecting 1,1-bis(4-hydroxyphenyl)-1-[4-{1-(4-hydroxyphenyl)-1-methylethyl}phenyl]ethane and 1-naphthoquinone-2-diazide-5-sulfonyl chloride to a condensation reaction, or a product obtained by subjecting tris(4-hydroxyphenyl)methane or tris(4-hydroxyphenyl)ethane and 1-naphthoquinone-2-diazide-5-sulfonyl chloride to a condensation reaction.

Examples of the dehydrochlorination agent include sodium carbonate, sodium hydroxide, sodium hydrogen carbonate, potassium carbonate, potassium hydroxide, trimethylamine, triethylamine, and pyridine. As the reaction solvent, for example, dioxane, acetone, methyl ethyl ketone, tetrahydrofuran, diethyl ether, and N-methyl-2-pyrrolidone are used.

It is preferable that o-quinone diazide sulfonyl chloride and the hydroxy compound and/or amino compound are blended such that the total number of moles of hydroxy groups and amino groups is 0.5 to 1 mol with respect to 1 mol of o-quinone diazide sulfonyl chloride. Preferred blending proportions of the dehydrochlorination agent and o-quinone diazide sulfonyl chloride are in the range of 0.95/1 molar equivalent to 1/0.95 molar equivalent.

From the viewpoint that the difference in the dissolution rate between an exposed part and an unexposed part becomes large, and sensitivity is further improved, the content of the component (C) may be 1 to 30 parts by mass, 2 to 25 parts by mass, or 3 to 20 parts by mass with respect to 100 parts by mass of the component (A).

### Low-Molecular Weight Compound Having Phenolic Hydroxyl Group

The photosensitive resin composition may include a low-molecular weight compound having a phenolic hydroxyl group. The low-molecular weight compound having a phenolic hydroxyl group is used in order to increase the dissolution rate of an exposed part when developing with an alkali aqueous solution and improve the sensitivity. By containing the low-molecular weight compound having a phenolic hydroxyl group, the low-molecular weight compound having a phenolic hydroxyl group reacts with the component (A) when the resin film after pattern formation is heated to cure, and a bridged structure is formed.

The molecular weight of the low-molecular weight compound having a phenolic hydroxyl group is preferably 2000 or less, and in consideration of the balance between the solubility in an alkali aqueous solution as well as the photosensitivity characteristics and the physical properties of the cured film, the molecular weight as the number average molecular weight (Mn) is preferably 94 to 2000, more preferably 108 to 2000, and even more preferably 108 to 1500.

As the low-molecular weight compound having a phenolic hydroxyl group, conventionally known ones can be used; however, a compound represented by the following Formula (2) is particularly preferable because the balance between the effect of promoting dissolution of an exposed part and the effect of preventing melting of the resin film at the time of curing is excellent.

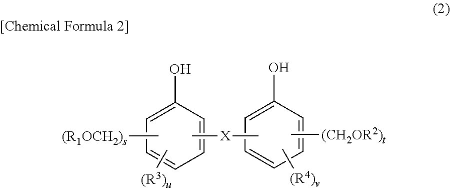

In Formula (2), X represents a single bond or a divalent organic group; R¹, R², R³, and R⁴ each independently represent a hydrogen atom or a monovalent organic group; s and t each independently represent an integer of 1 to 3; and u and v each independently represent an integer of 0 to 4.

In Formula (2), a compound in which X is a single bond is a biphenol (dihydroxybiphenyl) derivative. Examples of a divalent organic group represented by X include an alkylene group having 1 to 10 carbon atoms, such as a methylene group, an ethylene group, or a propylene group; an alkylidene group having 2 to 10 carbon atoms, such as an ethylidene group; an arylene group having 6 to 30 carbon atoms, such as a phenylene group; a group obtained by substituting some or all of the hydrogen atoms of one of these hydrocarbon groups with a halogen atom such as a fluorine atom; a sulfonyl group, a carbonyl group, an ether bond, a thioether bond, and an amide bond. Among these, a divalent organic group represented by the following Formula (3) is preferred.

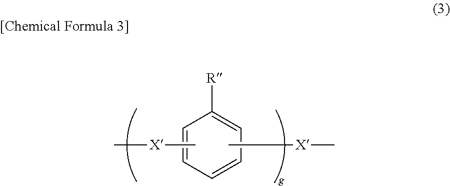

In Formula (3), X′ represents a single bond, an alkylene group (for example, an alkylene group having 1 to 10 carbon atoms), an alkylidene group (for example, an alkylidene group having 2 to 10 carbon atoms), a group obtained by substituting some or all of the hydrogen atoms of one of those groups with a halogen atom, a sulfonyl group, a carbonyl group, an ether bond, a thioether bond, or an amide bond; R″ represents a hydrogen atom, a hydroxy group, an alkyl group, or a haloalkyl group; g represents an integer of 1 to 10; and a plurality of R″s may be identical with or different from each other.

The blending amount of the low-molecular weight compound having a phenolic hydroxyl group may be 1 to 50 parts by mass, 2 to 30 parts by mass, or 3 to 25 parts by mass, with respect to 100 parts by mass of the component (A), from the viewpoints of the development time, the allowable range of the residual film ratio in the unexposed part, and the characteristics of the cured film.

### Compound Generating Acid Upon Heating

The photosensitive resin composition can include a compound generating acid upon heating. By using a compound generating acid upon heating, it is possible to produce acid when heating the patterned resin film, a reaction between the component (A), a compound having a glycidyl group, and a low-molecular weight compound having a phenolic hydroxyl group, that is, a thermal crosslinking reaction, is promoted, and the heat resistance of the patterned cured film is improved. In addition, since the compound generating acid upon heating generates acid even when irradiated with light, the solubility of the exposed part in an alkali aqueous solution is increased. Therefore, the difference in the solubility in an alkali aqueous solution between the unexposed part and the exposed part becomes larger, and resolution is further improved.

It is preferable that the compound generating acid upon heating is, for example, a compound generating acid upon heating up to 50° C. to 250° C. Examples of the compound generating acid upon heating include a salt formed from a strong acid and a base, such as an onium salt, and an imidosulfonate.

Examples of the onium salt include diaryliodonium salts such as an aryldiazonium salt and a diphenyliodonium salt; di(alkylaryl)iodonium salts such as a diaryliodonium salt and a di(t-butylphenyl)iodonium salt; trialkylsulfonium salts such as a trimethylsulfonium salt; dialkylmonoarylsulfonium salts such as dimethylphenylsulfonium salt; diarylmonoalkyliodonium salts such as diphenylmethylsulfonium salt; and triarylsulfonium salts. Among these, di(t-butylphenyl)iodonium salt of para-toluenesulfonic acid, di(t-butylphenyl)iodonium salt of trifluoromethanesulfonic acid, trimethylsulfonium salt of trifluoromethanesulfonic acid, dimethylphenylsulfonium salt of trifluoromethanesulfonic acid, diphenylmethylsulfonium salt of trifluoromethanesulfonic acid, di(t-butylphenyl)iodonium salt of nonafluorobutanesulfonic acid, diphenyliodonium salt of camphorsulfonic acid, diphenyliodonium salt of ethanesulfonic acid, dimethylphenylsulfonium salt of benzenesulfonic acid, and diphenylmethylsulfonium salt of toluenesulfonic acid are preferred.

As the salt formed from a strong acid and a base, in addition to the above-mentioned onium salts, salts formed from the following strong acids and bases, for example, a pyridinium salt, can also be used. Examples of the strong acids include arylsulfonic acids such as p-toluenesulfonic acid and benzenesulfonic acid; perfluoroalkylsulfonic acids such as camphorsulfonic acid, trifluoromethanesulfonic acid, and nonafluorobutanesulfonic acid; and alkylsulfonic acids such as methanesulfonic acid, ethanesulfonic acid, and butanesulfonic acid. Examples of the bases include pyridine, an alkylpyridine such as 2,4,6-trimethylpyridine, an N-alkylpyridine such as 2-chloro-N-methylpyridine, and a halogenated N-alkylpyridine.

As the imidosulfonate, for example, naphthoylimide sulfonate and phthalimide sulfonate can be used.

As the compound generating acid upon heating, in addition to those mentioned above, a compound having a structure represented by the following Formula (4) or a compound having a sulfonamide structure represented by the following Formula (5) can also be used.

R⁵R⁶C═N—O—SO₂—R⁷ (4)

—NH—SO₂—R⁸ (5)

In Formula (4), R⁵ is, for example, a cyano group; R⁶ is, for example, a methoxyphenyl group or a phenyl group; and R⁷ is, for example, an aryl group such as a p-methylphenyl group or a phenyl group, an alkyl group such as a methyl group, an ethyl group, or an isopropyl group, or a perfluoroalkyl group such as a trifluoromethyl group or a nonafluorobutyl group.

In Formula (5), R⁸ is, for example, an alkyl group such as a methyl group, an ethyl group, or a propyl group, an aryl group such as a methylphenyl group or a phenyl group, or a perfluoroalkyl group such as a trifluoromethyl group or nonafluorobutyl. Examples of a group to be bonded to the N atom of the sulfonamide structure represented by Formula (5) include 2,2′-bis(4-hydroxyphenyl)hexafluoropropane, 2,2′-bis(4-hydroxyphenyl)propane, and di(4-hydroxyphenyl) ether.

The blending amount of the compound generating acid upon heating may be 0.1 to 30 parts by mass, 0.2 to 20 parts by mass, or 0.5 to 10 parts by mass, with respect to 100 parts by mass of the component (A).

### Elastomer

The photosensitive resin composition according to the embodiment may contain an elastomer component. An elastomer is used to impart flexibility to a cured body of the photosensitive resin composition. As the elastomer, conventionally known ones can be used; however, it is preferable that the Tg of the polymer constituting the elastomer is 20° C. or lower.

Examples of the elastomer include a styrene-based elastomer, an olefin-based elastomer, a urethane-based elastomer, a polyester-based elastomer, a polyamide-based elastomer, an acryl-based elastomer, and a silicone-based elastomer. These can be used singly or in combination of two or more kinds thereof.

The blending amount of the elastomer may be 1 to 50 parts by mass or 5 to 30 parts by mass with respect to 100 parts by mass of the component (A). When the blending amount of the elastomer is 1 part by mass or more, the thermal shock resistance of the cured film tends to be improved, and when the blending amount is 50 parts by mass or less, there is a tendency that the resolution and the heat resistance of the obtained cured film are less likely to be deteriorated, while the compatibility with other components and the dispersibility are less likely to be deteriorated.

### Dissolution Promoting Agent

The photosensitive resin composition according to the embodiment may further contain a dissolution promoting agent. By blending a dissolution promoting agent into the photosensitive resin composition, the dissolution rate of the exposed part when developing with an alkali aqueous solution can be increased, and the sensitivity and resolution can be improved. As the dissolution promoting agent, conventionally known ones can be used. Examples of the dissolution promoting agent include compounds having a carboxy group, a sulfo group, or a sulfonamide group. The blending amount in the case of using a dissolution promoting agent can be determined based on the dissolution rate in an alkali aqueous solution, and for example, the blending amount can be set to 0.01 to 30 parts by mass with respect to 100 parts by mass of the component (A).

### Dissolution Inhibitor

The photosensitive resin composition according to the embodiment may further contain a dissolution inhibitor. A dissolution inhibitor is a compound lowering the solubility of the component (A) in an alkali aqueous solution and is used to control the residual film thickness, the development time, and the contrast. Examples of the dissolution inhibitor include diphenyliodonium nitrate, bis(p-tert-butylphenyl)iodonium nitrate, diphenyliodonium bromide, diphenyliodonium chloride, and diphenyliodonium iodide. The blending amount in the case of using a dissolution inhibitor may be 0.01 to 20 parts by mass, 0.01 to 15 parts by mass, or 0.05 to 10 parts by mass, with respect to 100 parts by mass of the component (A), from the viewpoints of the sensitivity and the allowable range of the development time.

### Coupling Agent

The photosensitive resin composition according to the embodiment may further contain a coupling agent. By blending a coupling agent into the photosensitive resin composition, the adhesiveness of the patterned cured film to be formed to the substrate can be increased. Examples of the coupling agent include an organic silane compound and an aluminum chelate compound.

Examples of the organic silane compound include vinyltriethoxysilane, γ-glycidoxypropyltriethoxysilane, γ-methacryloxypropyltrimethoxysilane, urea propyltriethoxysilane, methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl-n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, phenylsilanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, and 1,4-bis(dibutylhydroxysilyl)benzene.

The blending amount in the case of using a coupling agent is preferably 0.1 to 20 parts by mass, and more preferably 0.5 to 10 parts by mass, with respect to 100 parts by mass of the component (A).

### Surfactant or Leveling Agent

The photosensitive resin composition according to the embodiment may further contain a surfactant or a leveling agent. By blending a surfactant or a leveling agent into the photosensitive resin composition, coatability can be further improved. Specifically, for example, by containing a surfactant or a leveling agent, striation (unevenness of film thickness) can be further prevented, or developability can be further improved.

Examples of the surfactant or the leveling agent include polyoxyethylene lauryl ether, polyoxyethylene stearyl ether, polyoxyethylene oleyl ether, and polyoxyethylene octylphenol ether. Examples of commercially available products of the surfactant or the leveling agent include MEGAFAC F171, F173, R-08 (manufactured by DIC Corporation, trade names), FLUORAD FC430, FC431 (manufactured by Sumitomo 3M, Ltd., trade names), and organosiloxane polymers KP341, KBM303, KBM403, KBM803 (manufactured by Shin-Etsu Chemical Co., Ltd., trade names).

The blending amount in the case of using the surfactant or the leveling agent may be 0.001 to 5 parts by mass or 0.01 to 3 parts by mass with respect to 100 parts by mass of the component (A).

### Solvent

As the photosensitive resin composition according to the embodiment contains a solvent for dissolving or dispersing each component, application on a substrate can be facilitated, and a coating film having a uniform thickness can be formed.

Examples of the solvent include γ-butyrolactone, ethyl lactate, propylene glycol monomethyl ether acetate, benzyl acetate, n-butyl acetate, ethoxyethyl propionate, 3-methyl methoxypropionate, N-methyl-2-pyrrolidone, N,N-dimethylformamide, N,N-dimethylacetamide, dimethyl sulfoxide, hexamethyl phosphorylamide, tetramethylenesulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether. The solvents can be used singly or in combination of two or more kinds thereof.

The blending amount of the solvent is not particularly limited; however, it is preferable that the blending amount is adjusted such that the proportion of the solvent in the photosensitive resin composition is 20% to 90% by mass.

The photosensitive resin composition according to the present embodiment is capable of development using an alkali aqueous solution of sodium hydroxide, potassium hydroxide, sodium silicate, ammonia, ethylamine, diethylamine, triethylamine, triethanolamine, tetramethylammonium hydroxide (TMAH), and the like, or development using an organic solvent such as cyclopentanone or 2-methoxy-1-methylethyl acetate. By using the photosensitive resin composition according to the present embodiment, it is possible to form a patterned cured film having satisfactory close adhesiveness and HAST resistance with sufficiently highly sensitivity and resolution.

### Method for Producing Patterned Cured Film

A method for producing a patterned cured film (resist pattern) according to the present embodiment includes: a step of applying a photosensitive resin composition selected by the above-mentioned selection method on a portion or the entire surface of a substrate and drying the photosensitive resin composition to form a resin film (application and drying step); a step of exposing at least a portion of the resin film (exposure step); a step of developing the resin film after exposure to form a patterned resin film (development step); and a step of heating the patterned resin film that has been subjected to patterning (photosensitive resin film) (heat treatment step). Hereinafter, an example of each step will be described.

### Application and Drying Step

First, the photosensitive resin composition is applied on a substrate and dried to form a resin film. In this step, the photosensitive resin composition is spin-coated on a substrate such as a glass substrate, a semiconductor, a metal oxide insulator (for example, TiO₂ or SiO₂), or silicon nitride by using a spinner or the like, and a coating film is formed. The substrate on which this coating film is formed is dried by using a hot plate, an oven, or the like. The drying temperature may be 80° C. to 140° C., 90° C. to 135° C., or 100° C. to 130° C., and the drying time may be 1 to 7 minutes, 1 to 6 minutes, or 2 to 5 minutes. As a result, a resin film is formed on the substrate.

### Exposure Step

Next, in the exposure step, the resin film formed on the substrate is irradiated with active light rays such as ultraviolet radiation, visible rays, or a radiation through a mask. With regard to the above-mentioned photosensitive resin composition, since the component (A) is highly transparent to i-line, irradiation with i-line can be suitably used. After the exposure, post-exposure baking (PEB) may be carried out as necessary. The temperature of the post-exposure baking is preferably 70° C. to 140° C., and the time of the post-exposure baking is preferably 1 to 5 minutes.

### Development Step

In the development step, by removing an exposed part or an unexposed part of the resin film after the exposure step with a developing liquid, the resin film is patterned, and a patterned resin film is obtained. When the photosensitive resin composition is a positive-type composition, the exposed part is removed with the developing liquid. When the photosensitive resin composition is a negative-type composition, the unexposed part is removed with the developing liquid.

As the developing liquid in the case of developing using an alkali aqueous solution, for example, an alkali aqueous solution of sodium hydroxide, potassium hydroxide, sodium silicate, ammonia, ethylamine, diethylamine, triethylamine, triethanolamine, tetramethylammonium hydroxide (TMAH), or the like is suitably used. It is preferable that the base concentration of these aqueous solutions is adjusted to 0.1% to 10% by mass. It is also possible to add an alcohol or a surfactant to the above-described developing liquid and use the mixture. Each of these may be blended in an amount in the range of 0.01 to 10 parts by mass or 0.1 to 5 parts by mass with respect to 100 parts by mass of the developing liquid.

As the developing liquid in the case of developing using an organic solvent, for example, good solvents such as cyclopentanone, N,N-dimethylformamide, dimethyl sulfoxide, N,N-dimethylacetamide, N-methyl-2-pyrrolidone, γ-butyrolactone, and acetic acid esters; and mixed solvents of these good solvents with poor solvents such as lower alcohols, water, and aromatic hydrocarbons, are used.

### Heat Treatment Step

In the heat treatment step, a patterned cured film (resist pattern) can be formed by heat-treating the patterned resin film. The heating temperature in the heat treatment step may be 170° C. to 260° C., 180° C. to 250° C., or 190° C. to 240° C., from the viewpoint of sufficiently preventing damage to electronic devices due to heat.

The heat treatment can be carried out by, for example, using an oven such as a quartz tube furnace, a hot plate, rapid thermal annealing, a vertical diffusion furnace, an infrared curing furnace, an electron beam curing furnace, or a microwave curing furnace. In addition, either an air atmosphere or an inert atmosphere of nitrogen or the like can be selected; however, it is desirable to use nitrogen since nitrogen can prevent oxidation of the pattern. Since the heating temperature in the above-mentioned range is lower than the conventional heating temperature, the damage to the substrate and electronic devices can be suppressed to a low level. Therefore, an electronic device can be produced with a high yield by using the method for producing a patterned cured film according to the present embodiment.

The heat treatment time in the heat treatment step may be any time sufficient for the photosensitive resin composition to cure; however, from the viewpoint of the balance with the operation efficiency, the heat treatment time is preferably approximately 5 hours or less. The heating time may be 1.0 to 2.5 hours, 1.5 to 2.5 hours, or 1.8 to 2.2 hours.

The heat treatment can also be carried out by using a microwave curing apparatus or a frequency-variable microwave curing apparatus in addition to the above-mentioned ovens. By using these apparatuses, it is possible to effectively heat only the resin film while maintaining the temperature of the substrate and the electronic devices at a desired temperature (for example, 200° C. or lower).

In a frequency-variable microwave curing apparatus, since microwaves are irradiated in a pulsed manner while changing the frequency, standing waves can be prevented, and the substrate surface can be heated uniformly. In addition, in a case where the substrate includes metal wiring as is the case of an electronic component that will be described below, when microwaves are irradiated in a pulsed manner while changing the frequency, the occurrence of electrical discharge from metal can be prevented, and the electronic component can be protected from destruction. Furthermore, when heating is performed by using frequency-variable microwaves, the physical properties of the cured film are less likely to be deteriorated even when the curing temperature is lowered, as compared with the case of using an oven (see J. Photopolym. Sci. Technol., 18, 327-332 (2005)).

The frequency of the frequency-variable microwaves is in the range of 0.5 to 20 GHz; however, the frequency may be practically in the range of 1 to 10 GHz or 2 to 9 GHz. In addition, although it is desirable that the frequency of the microwaves to be irradiated is changed continuously; however, in reality, the frequency is changed stepwise and irradiated. At that time, as the time for irradiating microwaves of a single frequency is set to be as short as possible, standing waves, electrical discharge from metal, and the like are less likely to occur, and therefore, the irradiation time for microwaves is preferably 1 millisecond or less, and more preferably 100 microseconds or less.

The power output of the microwaves to be irradiated may vary depending on the size of the apparatus or the amount of the body to be heated; however, the power output is approximately in the range of 10 to 2000 W and may be practically 100 to 1000 W, 100 to 700 W, or 100 to 500 W. When the power output is 10 W or greater, the body to be heated is easily heated in a short period of time, and when the power output is 2000 W or less, rapid temperature increase is less likely to occur.

It is preferable that the microwaves are irradiated by being turned on and off in a pulsed manner. By irradiating microwaves in a pulsed manner, the set heating temperature can be maintained, and in addition, it is preferable from the viewpoint that damage to the cured film and the base material can be avoided. The time for a single irradiation of microwaves in a pulsed manner may vary depending on the conditions; however, the time is preferably approximately 10 seconds or less.

According to the method for producing a patterned cured film as described above, a patterned cured film having satisfactory heat resistance is obtained with sufficiently high sensitivity and resolution. The patterned cured film according to the present embodiment can be used as an interlayer insulating layer or a surface protection layer for semiconductor elements.

### Production Process for Semiconductor Device

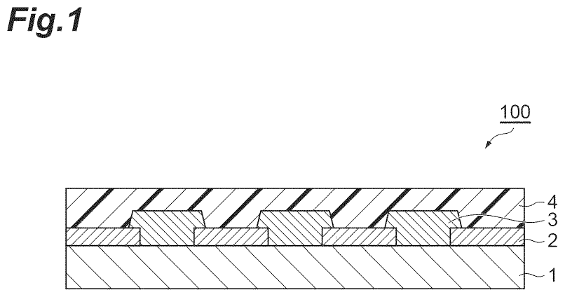

As an example of the method for producing a patterned cured film (resist pattern) according to the present embodiment, the production process for a semiconductor device will be described based on the drawings. FIGS. 1 to 5 are schematic cross-sectional views illustrating an embodiment of the production process for a semiconductor device having a multilayer wiring structure.

First, a structure 100 shown in FIG. 1 is prepared. The structure 100 includes a semiconductor substrate 1 such as a Si substrate having a circuit element; a protective film 2 such as a silicon oxide film for coating the semiconductor substrate 1 having a predetermined pattern through which the circuit element is exposed; a first conductor layer 3 formed on the exposed circuit element; and an interlayer insulating layer 4 made of a polyimide resin or the like and formed on the protective film 2 and the first conductor layer 3 by a spin coating method or the like.

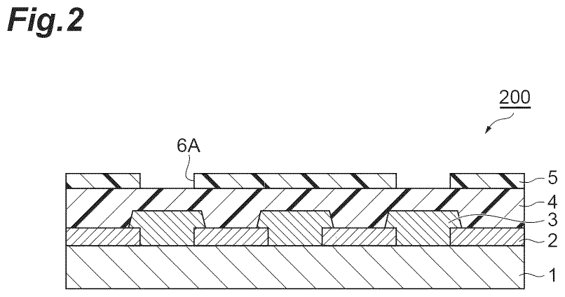

Next, a structure 200 shown in FIG. 2 is obtained by forming a photosensitive resin layer 5 having a window part 6A on the interlayer insulating layer 4. The photosensitive resin layer 5 is formed by, for example, applying a photosensitive resin composition by a spin coating method. The window part 6A is formed such that the interlayer insulating layer 4 at a predetermined portion is exposed by a known photoetching technology.

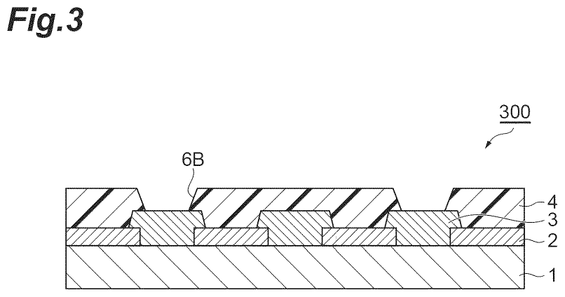

After a window part 6B is formed by etching the interlayer insulating layer 4, the photosensitive resin layer 5 is removed, and a structure 300 shown in FIG. 3 is obtained. For the etching of the interlayer insulating layer 4, a dry etching means using a gas such as oxygen or carbon tetrafluoride can be used. Due to this etching, the interlayer insulating layer 4 at the portion corresponding to the window part 6A is selectively removed, and an interlayer insulating layer 4 having the window part 6B provided such that the first conductor layer 3 is exposed, is obtained. Next, the photosensitive resin layer 5 is removed by using an etching solution that corrodes only the photosensitive resin layer 5 without corroding the first conductor layer 3 exposed through the window part 6B.

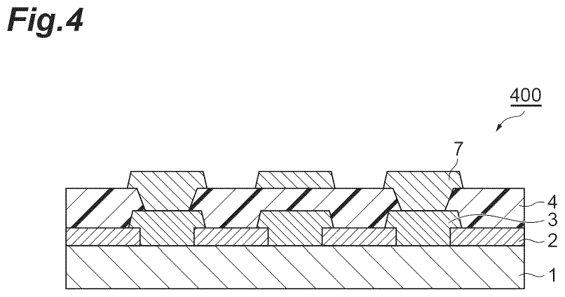

Furthermore, a second conductor layer 7 is formed at a portion corresponding to the window part 6B, and a structure 400 shown in FIG. 4 is obtained. For the formation of the second conductor layer 7, a known photoetching technology can be used. As a result, electrical connection between the second conductor layer 7 and the first conductor layer 3 is achieved.

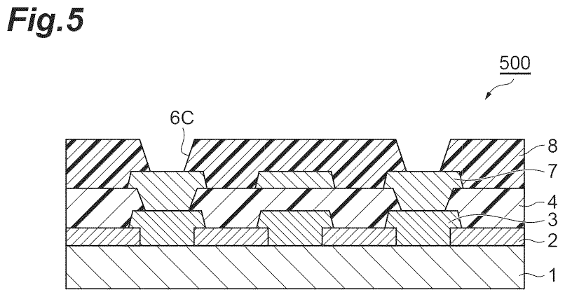

Lastly, a surface protection layer 8 is formed on the interlayer insulating layer 4 and the second conductor layer 7, and a semiconductor device 500 shown in FIG. 5 is obtained. In the present embodiment, the surface protection layer 8 is formed as follows. First, the photosensitive resin composition according to the above-mentioned embodiment is applied on the interlayer insulating layer 4 and the second conductor layer 7 by a spin coating method and dried to form a resin film. Next, predetermined portions are irradiated with light through a mask in which a pattern corresponding to the window part 6C is drawn, and then the predetermined portions are developed to pattern the resin film. Thereafter, the resin film is cured by heating to form a film as the surface protection layer 8. This surface protection layer 8 protects the first conductor layer 3 and the second conductor layer 7 from external stress, α-radiation, and the like, and the resulting semiconductor device 500 has excellent reliability.

Incidentally, in the above-described embodiment, a method for producing a semiconductor device having a two-layered wiring structure has been described; however, in the case of forming a multilayer wiring structure with three or more layers, each layer can be formed by repeatedly carrying out the above-mentioned steps. That is, it is possible to form a multilayer pattern by repeatedly carrying out each step of forming the interlayer insulating layer 4 and each step of forming the surface protection layer 8. In addition, with regard to the above-described example, it is possible to form not only the surface protection layer 8 but also the interlayer insulating layer 4 by using the photosensitive resin composition according to the present embodiment.

### Electronic Component

An electronic component according to the present embodiment will be described. The electronic component according to the present embodiment has a patterned cured film formed by the above-mentioned production method as an interlayer insulating layer or a surface protection layer. The electronic component includes a semiconductor device, a multilayer wiring board, various electronic devices, and the like. The above-described patterned cured film can be used specifically as a surface protection layer or an interlayer insulating layer of a semiconductor device, an interlayer insulating layer of a multilayer wiring board, or the like. The electronic component according to the present embodiment can adopt various structures without any particular limitation, except that the electronic component has a surface protection layer or an interlayer insulating layer formed by using the above-mentioned photosensitive resin composition.

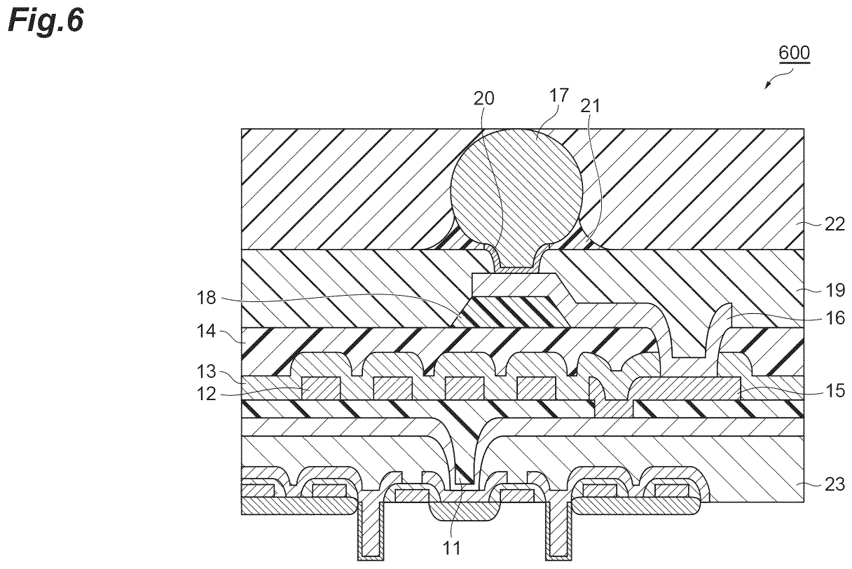

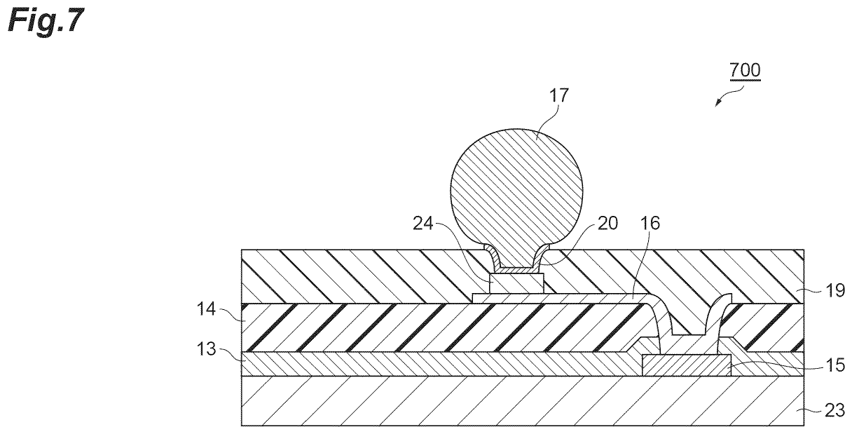

The above-mentioned photosensitive resin composition is also excellent in terms of stress relaxation properties, adhesiveness, and the like, the photosensitive resin composition can also be used as various structural materials in packages of various structures developed in recent years. The cross-sectional structure of an example of such a years. semiconductor device is shown in FIGS. 6 and 7.

FIG. 6 is a schematic cross-sectional view illustrating a wiring structure as an embodiment of a semiconductor device. The semiconductor device 600 shown in FIG. 6 includes: a silicon chip 23; an interlayer insulating layer 11 provided on one surface side of the silicon chip 23; an Al wiring layer 12 formed on the interlayer insulating layer 11 and having a pattern including a pad part 15; an insulating layer 13 (for example, P—SiN layer) and a surface protection layer 14 laminated sequentially on the interlayer insulating layer 11 and the Al wiring layer 12 while forming an opening on the pad part 15; an island-shaped core 18 disposed in the vicinity of the opening on the surface protection layer 14; and a rewiring layer 16 extending on the surface protection layer 14 so as to be in contact with the pad part 15 within the opening of the insulating layer 13 and the surface protection layer 14 and also to be in contact with a surface of the core 18, the surface being on the opposite side of the surface protection layer 14. Furthermore, the semiconductor device 600 includes: a cover coat layer 19 formed to cover the surface protection layer 14, the core 18, and the rewiring layer 16 and having an opening formed in a portion of the rewiring layer 16 on the core 18; an electroconductive ball 17 connected to the rewiring layer 16, with a barrier metal 20 interposed therebetween, in the opening of the cover coat layer 19; a collar 21 holding the electroconductive ball; and an underfill 22 provided on the cover coat layer 19 around the electroconductive ball 17. The electroconductive ball 17 is used as an external connection terminal and is formed from solder, gold, or the like. The underfill 22 is provided in order to relieve stress when the semiconductor device 600 is packaged.

FIG. 7 is a schematic cross-sectional view illustrating a wiring structure as an embodiment of the semiconductor device. In the semiconductor device 700 of FIG. 7, an Al wiring layer (not shown in the diagram) and the pad part 15 of the Al wiring layer are formed on the silicon chip 23, and an insulating layer 13 is formed on top of the Al wiring layer and the pad part, while the surface protection layer 14 of the element is further formed. On the pad part 15, a rewiring layer 16 is formed, and this rewiring layer 16 extends to the top of the connection part 24 with the electroconductive ball 17. Furthermore, on the surface protection layer 14, the cover coat layer 19 is formed. The rewiring layer 16 is connected to the electroconductive ball 17, with a barrier metal 20 interposed therebetween.

With regard to the semiconductor device of FIGS. 6 and 7, the above-mentioned photosensitive resin composition can be used as a material for forming not only the interlayer insulating layer 11 and the surface protection layer 14 but also the cover coat layer 19, the core 18, the collar 21, the underfill 22, or the like. A cured body obtained using the above-mentioned photosensitive resin composition has excellent adhesiveness to metal layers such as an Al wiring layer 12 and a rewiring layer 16, a sealing material, and the like and also has a high stress relaxation effect, and therefore, a semiconductor device using this cured body for the cover coat layer 19, the core 18, the collar 21 such as solder, and the underfill 22 used in flip chips or the like, has extremely excellent reliability.

It is particularly suitable to use the photosensitive resin composition according to the present embodiment for a surface protection layer 14 and/or a cover coat layer 19 of a semiconductor device having a rewiring layer 16 in FIGS. 6 and 7. The film thickness of the surface protection layer or the cover coat layer may be, for example, 3 to 20 μm or 5 to 15 μm.

By using the method for setting the photosensitive resin composition according to the present embodiment, a cured film having excellent HAST resistance can be formed. By using the cured film according to the present embodiment as an interlayer insulating layer or a surface protection layer, an electronic component such as a semiconductor device having excellent reliability can be obtained with a high yield at a satisfactory yield percentage.

### EXAMPLES

Hereinafter, the present disclosure will be described more specifically by way of Examples. However, the present invention is not intended to be limited to the following Examples.

The materials used in order to prepare the photosensitive resin compositions of Examples and Comparative Examples will be described below.

As the component (A), P-1 to P-6 were prepared. The Mw and Tg of P-1 to P-6 will be collectively shown in Table 1.
(P-1) Cresol novolac resin (m-cresol/p-cresol (molar ratio)=60/40, Mw=12000, Tg=165° C., manufactured by Asahi Yukizai Corporation, trade name: EP4020G)
(P-2) Cresol novolac resin (m-cresol/p-cresol (molar ratio)=60/40, Mw=4500, Tg=150° C., manufactured by Asahi Yukizai Corporation, trade name: EP4080G)
(P-3)

In a flask, 35.6 g of 4-hydroxyphenyl methacrylate, 78.0 g of 2-hydroxyethyl methacrylate, 20.0 g of N-acryloyloxyethyl hexahydrophthalimide (manufactured by Toagosei Co., Ltd., trade name: M-140), 300 g of N,N-dimethylacetamide (DMAc), and 6.43 g of azoisobutyronitrile (AIBN) were introduced, and the mixture was caused to react at 80° C. for 6 hours in a nitrogen atmosphere. After 200 g of methanol was added thereto, the reaction mixture was slowly added dropwise to 1000 g of ion-exchanged water, and a polymer thus precipitated was filtered and dried to obtain P-3.
(P-4)

7.07 g of 3,3′,4,4′-diphenyl ether tetracarboxylic acid dianhydride (ODPA) and 4.12 g of 2,2′-dimethylbiphenyl-4,4′-diamine (DMAP) were dissolved in 30 g of N-methyl-2-pyrrolidone (NMP), the solution was stirred at 30° C. for 4 hours and then stirred overnight at room temperature (25° C.), and a polyamic acid solution was obtained. 9.45 g of trifluoroacetic anhydride was added to the polyamic acid solution under water cooling, the mixture was stirred at 45° C. for 3 hours, subsequently 7.08 g of 2-hydroxyethyl methacrylate (HEMA) was added thereto, and a reaction was carried out. This reaction liquid was added dropwise to distilled water, and a precipitate was deposited. The precipitate was separated by filtration and dried under reduced pressure to obtain P-4, which was a polyamic acid ester (polyimide precursor).
(P-5)

7.07 g of ODPA, 0.831 g of HEMA, and a catalytic amount of 1,4-diazabicyclo[2.2.2]octane were dissolved in 30 g of NMP, and the solution was stirred at 45° C. for 1 hour and then cooled to 25° C. A solution obtained by dissolving 4.12 g of DMAP in NMP was added thereto, and the mixture was stirred at 30° C. for 4 hours. Thereafter, the mixture was stirred overnight at room temperature, and a polyamic acid solution was obtained. 9.45 g of trifluoroacetic anhydride was added to the polyamic acid solution, the mixture was stirred at 45° C. for 3 hours, 7.08 g of HEMA and 0.01 g of benzoquinone were added thereto, and while the mixture was stirred at 45° C. for 20 hours, a reaction was carried out. This reaction liquid was added dropwise to distilled water, and a precipitate was deposited. The precipitate was separated by filtration and dried under reduced pressure to obtain P-5, which was a polyimide precursor.
(P-6)

Into a 300-mL flask equipped with a stirrer, a thermometer, a nitrogen purging apparatus (nitrogen inlet tube), and a reflux condenser with a moisture receiver, 14.64 g (0.04 mol) of 2,2-bis(3-amino-4-hydroxyphenyl)hexafluoropropane (manufactured by Central Glass Co., Ltd., trade name: BIS-AP-AF), 19.48 g (0.045 mol) of polyoxypropylenediamine (manufactured by BASF, trade name: D-400), 2.485 g (0.01 mol) of 3,3′-(1,1,3,3-tetramethyldisiloxane-1,3-diyl)bispropylamine (manufactured by Dow Corning Toray Co., Ltd., trade name: BY16-871EG), all of which are amine components, and 80 g of NMP were introduced, and the mixture was stirred to dissolve the amine components in the solvent. While the flask was cooled in an ice bath, 31 g (0.1 mol) of ODPA was added little by little into the solution in the flask. After completion of the addition, the temperature of the solution was raised to 180° C. while blowing nitrogen gas, the solution was kept at the temperature for 5 hours, and an NMP solution of P-6, which was a polyimide having a hydroxyl group, was obtained.

TABLE 1

| Component (A) | | Mw | Tg (° C.) |
|---|---|---|---|
| P-1 | Cresol novolac resin | 12000 | 165 |
| P-2 | Cresol novolac resin | 4500 | 150 |
| P-3 | Acrylic resin having phenolic hydroxyl group | 22000 | 100 |
| P-4 | Polyimide precursor | 40000 | 170 |
| P-5 | Polyimide precursor | 25500 | 150 |
| P-6 | Polyimide having hydroxyl group | 42000 | 65 |

As the component (B), thermosetting compounds (B-1) and (B-2) and photopolymerizable compounds (B-3) and (B-4) were prepared.
(B-1) 4,4′,4″-Ethylidenetris[2,6-(methoxymethyl)phenol] (manufactured by Honshu Chemical Industry Co., Ltd., trade name: HMOM-TPHAP)
(B-2) Bisphenol A bis(triethylene glycol glycidyl ether) ether (manufactured by New Japan Chemical Co., Ltd., trade name: BEO-60E)
(B-3) Tetraethylene glycol dimethacrylate (manufactured by Shin-Nakamura Chemical Co., Ltd., trade name: TEGDMA)
(B-4) Ethoxypentaerythritol tetraacrylate (manufactured by Shin-Nakamura Chemical Co., Ltd., trade name: ATM-4E)

As the component (C), the following photosensitizers were prepared.
(C-1) 1-Naphthoquinone-2-diazide-5-sulfonic acid ester of tris (4-hydroxyphenyl)methane (esterification ratio about 95%)
(C-2) Ethanone, 1-[9-ethyl-6-(2-methylbenzoyl)-9H-carbazol-3-yl], 1-(O-acetyloxime) (manufactured by BASF Japan Ltd., trade name: IRGACURE OXE02”)
(C-3) 1-Phenyl-1,2-propanedione-2-(O-ethoxycarbonyl) oxime (manufactured by Lambson, Ltd., trade name: G-1820(PDO))

### Fabrication of Photosensitive Resin Composition

### Examples 1 to 4

Components (A) to (C) in the blending amounts (parts by mass) indicated in Table 2, 120 parts by mass of ethyl lactate as a solvent, and 2 parts by mass of a 50% by mass ethanol solution of 3-glycidoxypropyltriethoxysilane (manufactured by Shin-Etsu Chemical Co., Ltd., trade name: KBE-403) as a coupling agent were mixed. The mixture was filtered under pressure by using a filter made of a polytetrafluoroethylene resin with 3-μm pores to prepare a photosensitive resin composition.

### Examples 5 to 7

Components (A) to (C) in the blending amounts (parts by mass) indicated in Table 2, 150 parts by mass of NMP as a solvent, and 2 parts by mass of a 50% by mass ethanol solution of KBE-403 were mixed. The mixture was filtered under pressure by using a filter made of a polytetrafluoroethylene resin with 3-μm pores to prepare a photosensitive resin composition.

### Comparative Examples 1 to 3

Components (A) to (C) in the blending amounts (parts by mass) indicated in Table 3, 120 parts by mass of ethyl lactate as a solvent, and 2 parts by mass of a 50% by mass ethanol solution of KBE-403 were mixed. The mixture was filtered under pressure by using a filter made of a polytetrafluoroethylene resin with 3-μm pores to prepare a photosensitive resin composition.

### Comparative Examples 4 and 5

Components (A) to (C) in the blending amounts (parts by mass) indicated in Table 3, 150 parts by mass of NMP as a solvent, and 2 parts by mass of a 50% by mass ethanol solution of KBE-403 were mixed. The mixture was filtered under pressure by using a filter made of a polytetrafluoroethylene resin with 3-μm pores to prepare a photosensitive resin composition.

### Evaluation of Photosensitive Resin Composition

### Fabrication of Cured Film

A photosensitive resin composition was applied on a 6-inch silicon wafer by using a spin coater such that the thickness after curing was 12 μm, and this was heated on a hot plate at 120° C. for 3 minutes to form a resin film. The silicon wafer with a resin film formed thereon was heated at the temperature indicated in Table 2 for 2 hours in a nitrogen atmosphere to form a cured film on the silicon wafer.

### Weight Loss Ratio

About 10 mg of the cured film peeled off from the silicon wafer was put in an aluminum pan, and the temperature was raised from 25° C. to 300° C. using a simultaneous thermogravimetric-differential thermal analyzer (manufactured by Hitachi High-Tech Science Corporation, trade name: STA7300) at a nitrogen flow rate of 400 mL/min and a temperature increase rate of 10° C./min in a nitrogen atmosphere. The weight loss ratio of the cured film at 300° C. was calculated.

### Storage Modulus

The cured film was cut out into a strip form having a width of 10 mm and a length of 100 mm, and a strip sample was fabricated. A viscoelasticity test of the strip sample was performed using a dynamic viscoelasticity measuring apparatus (manufactured by UBM Co., Ltd., trade name: Rheogel-E4000) in a temperature range of 40° C. to 350° C. at a distance between chucks of 20 mm, a frequency of 10 Hz, and a temperature increase rate of 5° C./min, and the storage modulus at 130° C. was measured.

### Glass Transition Temperature

The temperature showing the maximum value of tan δ measured in the above-mentioned viscoelasticity test was designated as glass transition temperature (Tg).

### Moisture Absorption Rate

The silicon wafer with the cured film formed thereon was left to stand in a constant-temperature constant-humidity chamber (manufactured by ESPEC CORP., trade name: EHS-221MD) set at a relative temperature of 85% and 130° C. for 24 hours. The inside of the constant-temperature constant-humidity chamber was lowered to 50° C., and a measurement sample for the moisture absorption rate was fabricated. The cured film of the measurement sample was peeled off from the silicon wafer, and the weight loss ratio was measured by using a simultaneous thermogravimetric-differential thermal analyzer (manufactured by Hitachi High-Tech Science Corporation, trade name: STA7300) under the conditions of a temperature increase rate of 10° C./min, a nitrogen flow of 400 mL/min, and a temperature range of 25° C. to 150° C. A measurement sample fabricated under similar conditions was dried at 130° C. for 2 hours, and then the weight loss ratio was measured by a similar method. The difference in the weight loss ratio at 150° C. of these was calculated as the moisture absorption rate.

### Water Absorption Rate

The cured film whose weight was measured in advance was immersed in ion-exchanged water at 25° C. for 24 hours. The cured film was taken out, the weight of the cured film was measured, and the weight difference before and after the immersion was designated as the water absorption rate.

### HAST Resistance

Substrates on which comb-shaped wiring of 5 μm/5 μm, 3 μm/3 μm, and 2 μm/2 μm were each prepared by using a semi-additive process (SAP). A photosensitive resin composition was spin-coated on the comb-shaped wiring and then was dried at 120° C. for 3 minutes, the photosensitive resin composition was exposed (exposure amount: 500 mJ/cm², broadband exposure), and a resin film was formed. Next, the resin film was heated at the temperature indicated in Table 2 or 3 for 2 hours in a nitrogen atmosphere to fabricate a sample for evaluation. Under the conditions of a humidity of 85% and 130° C., the sample for evaluation was left to stand in a state in which a voltage of 3.3 V was applied to the comb-shaped wiring. The resistance value between the anode and the cathode was measured every hour. A case in which a resistance value of 1×10⁶Ω or more was maintained for 200 hours or longer was rated as “A”; a case in which a resistance value of 1×10⁶Ω or more was maintained for 100 hours or longer and shorter than 200 hours was rated as “B”; and a case in which a resistance value of 1×10⁶Ω or more was maintained for shorter than 100 hours was rated as “C”.

TABLE 2

| Example | | 1 | 2 | 3 | 4 | 5 | 6 | 7 |
|---|---|---|---|---|---|---|---|---|
| (A) | P-1 | 60 | 60 | 50 | 60 | — | — | — |
| | P-2 | 40 | 40 | 50 | — | — | — | — |
| | P-3 | — | — | — | 40 | — | — | — |
| | P-4 | — | — | — | — | 100 | 100 | — |
| | P-5 | — | — | — | — | — | — | 100 |
| | P-6 | — | — | — | — | — | — | — |
| (B) | B-1 | 15 | 15 | 15 | 15 | — | — | — |
| | B-2 | 10 | 10 | 10 | 10 | — | — | — |
| | B-3 | — | — | — | — | 6 | 6 | 6 |
| | B-4 | — | — | — | — | 4 | 4 | 4 |
| (C) | C-1 | 15 | 15 | 15 | 15 | — | — | — |
| | C-2 | — | — | — | — | 0.3 | 0.3 | 0.3 |
| | C-3 | — | — | — | — | 4 | 4 | 4 |
| KBE-403 | | 1 | 1 | 1 | 1 | 1 | 1 | 1 |
| Curing temperature (° C.) | | 230 | 200 | 230 | 230 | 230 | 200 | 230 |
| Weight loss ratio (%) @300° C. | | 3.4 | 4.2 | 3.7 | 3.9 | 4.3 | 4.7 | 4.7 |
| Storage modulus (GPa) @130° C. | | 2.9 | 2.6 | 2.8 | 2.2 | 2 | 1.7 | 1.3 |
| Tg (° C.) | | 256 | 243 | 252 | 259 | 227 | 224 | 204 |
| Moisture absorption rate (%) | | 0.7 | 0.9 | 0.8 | 0.7 | 0.7 | 0.8 | 0.8 |
| Water absorption rate (%) | | 0.5 | 0.8 | 0.5 | 0.6 | 0.7 | 0.7 | 0.7 |
| HAST | 5 μm/5 μm | A | A | A | A | A | A | A |
| resistance | 3 μm/3 μm | A | A | A | A | A | B | B |
| | 2 μm/3 μm | A | B | A | B | B | B | B |

TABLE 3

| Comparative Example | | 1 | 2 | 3 | 4 | 5 |
|---|---|---|---|---|---|---|
| (A) | P-1 | 60 | 60 | 40 | — | — |
| | P-2 | 40 | 40 | — | — | — |
| | P-3 | — | — | — | — | — |
| | P-4 | — | — | — | — | — |
| | P-5 | — | — | — | 100 | 100 |
| | P-6 | — | — | 60 | — | — |
| (B) | B-1 | 15 | 30 | 15 | — | — |
| | B-2 | 10 | 15 | 10 | — | — |
| | B-3 | — | — | — | 6 | 6 |
| | B-4 | — | — | — | 4 | 4 |
| (C) | C-1 | 15 | 20 | 15 | — | — |
| | C-2 | — | — | — | 0.3 | 0.3 |
| | C-3 | — | — | — | 4 | 4 |
| KBE-403 | | 1 | — | 1 | 1 | 1 |
| Curing temperature (° C.) | | 160 | 230 | 230 | 160 | 350 |
| Weight loss ratio (%) @300° C. | | 7.8 | 6.4 | 6.4 | 8.4 | 0.7 |
| Storage modulus (GPa) @130° C. | | 2.2 | 3.2 | 0.8 | 0.7 | 1.5 |
| Tg (° C.) | | 186 | 261 | 191 | 194 | 215 |
| Moisture absorption rate (%) | | 2.3 | 0.8 | 1.5 | 1.9 | 0.6 |
| Water absorption rate (%) | | 1.2 | 0.7 | 1.1 | 1.4 | 0.4 |
| HAST | 5 μm/5 μm | C | A | A | C | C |
| resistance | 3 μm/3 μm | C | C | C | C | C |
| | 2 μm/3 μm | C | C | C | C | C |

### REFERENCE SIGNS LIST

1: semiconductor substrate, 2: protective film, 3: first conductor layer, 4: interlayer insulating layer, 5: photosensitive resin layer, 6A, 6B, 6C: window part, 7: second conductor layer, 8: surface protection layer, 11: interlayer insulating layer, 12: Al wiring layer, 13: insulating layer, 14: surface protection layer, 15: pad part, 16: rewiring layer, 17: electroconductive ball, 18: core, 19: cover coat layer, 20: barrier metal, 21: collar, 22: underfill, 23: silicon chip, 24: connection part, 100, 200, 300, 400: structure, 500: semiconductor device, 600: semiconductor device, 700: semiconductor device.

1. A method for selecting a photosensitive resin composition, the method comprising:
a step of applying a photosensitive resin composition on a substrate and drying the photosensitive resin composition to form a resin film;
a step of heat-treating the resin film in a nitrogen atmosphere to obtain a cured film; and
a step of raising temperature from 25° C. to 300° C. at a rate of 10° C./min in a nitrogen atmosphere and then measuring weight loss of the cured film,
wherein a photosensitive resin composition capable of producing the cured film having a weight loss ratio at 300° C. of 1.0% to 6.0% is selected.

2. The method for selecting a photosensitive resin composition according to claim 1, wherein a temperature for heat-treating the resin film is 170° C. to 260° C.

3. The method for selecting a photosensitive resin composition according to claim 1, wherein a storage modulus at 130° C. of the cured film is 1.0 GPa or more.

4. The method for selecting a photosensitive resin composition according to claim 1, wherein a moisture absorption rate obtained after leaving the cured film to stand for 24 hours under conditions of 130° C. and 85 RH % is 1.2% or less.

5. The method for selecting a photosensitive resin composition according to claim 1, wherein a glass transition temperature of the cured film is 200° C. or higher.

6. A method for producing a patterned cured film, the method comprising:
a step of applying a photosensitive resin composition selected by the method for selecting a photosensitive resin composition according to claim 1 on a portion or an entire surface of a substrate and drying the photosensitive resin composition to form a resin film;
a step of exposing at least a portion of the resin film;
a step of developing the resin film after exposure to form a patterned resin film; and
a step of heating the patterned resin film to obtain a patterned cured film.

7. The method for producing a patterned cured film according to claim 6, wherein the substrate has a wiring pattern having a line width of 3 μm or less and an interline distance of 3 μm or less.

8. A method for producing a semiconductor device including a patterned cured film formed by the method for producing a patterned cured film according to claim 6 as an interlayer insulating layer or a surface protection layer.

9. A cured film of a photosensitive resin composition used for filling spaces between wiring lines with a line width of 3 μm or less and an interline distance of 3 μm or less,
wherein a weight loss ratio measured by raising temperature of the cured film from 25° C. to 300° C. at a rate of 10° C./min in a nitrogen atmosphere is 1.0% to 6.0%.

10. The cured film according to claim 9, wherein a storage modulus at 130° C. is 1.0 GPa or more.

11. The cured film according to claim 9, wherein a moisture absorption rate after leaving the cured film to stand for 24 hours under conditions of 130° C. and 85 RH % is 1.2% or less.

12. The cured film according to claim 9, wherein a glass transition temperature is 200° C. or higher.

13. A semiconductor device comprising the cured film according to claim 9 as an interlayer insulating layer or a surface protection layer.
